(19) United States
(12) Patent Application Publication
(10) Pub. No.: US 2007/0264766 A1
(43) Pub. Date: Nov. 15, 2007

(54) NOS NON-VOLATILE MEMORY CELL AND METHOD OF OPERATING THE SAME

(75) Inventors: Chrong-Jung Lin, Taipei County (TW); Ya-Chin King, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: EMEMORY TECHNOLOGY INC., Hsin-Chu (TW)

(21) Appl. No.: 11/746,061

(22) Filed: May 9, 2007

(30) Foreign Application Priority Data
May 9, 2006 (TW) 95116464

(51) Int. Cl. H01L 21/8238; H01L 21/336

(52) U.S. Cl. 438/199; 438/257

(57) ABSTRACT

A nitride/oxide/semiconductor (NOS) non-volatile memory cell formed in an n-well, having no control gate and capable of storing two bits is provided. The NOS non-volatile memory cell includes at least one NO (nitride layer, oxide layer) storage gate capable of storing one bit of data in the nitride layer adjacent to the source and the drain, respectively. The source and the drain are regions heavily doped with p-type impurities. The NOS non-volatile memory cell is capable of doubling the storage capacity of a flash memory chip having the same size.

### CROSS-REFERENCE TO RELATED APPLICATION

This application claims the priority benefit of Taiwan application serial no. 95116464, filed on May 9, 2006. All disclosure of the Taiwan application is incorporated herein by reference.

### BACKGROUND OF THE INVENTION

1. Field of the Invention

The present invention generally relates to a flash memory structure, in particular, to a NOS non-volatile memory cell having no control gate and capable of storing two bits of data and a method of operating the same.

2. Description of Related Art

Flash memory disk is one kind of non-volatile storage device that requires no electrical power to retain the data stored therein. Furthermore, a typical memory cell is capable of saving the data for at least 10 years. Unlike a hard disk storage device that requires a stepping motor to drive a read/write magnetic head over a disk to access the data, for example, to magnetize (write) a small magnetic region or determine (read) the magnetized state of a small magnetic region, there is no electromechanical motion in the flash memory disk. Data in the flash memory dish can be access by applying different voltages to the electrodes of the device. Since no stepping motor is used, the flash memory disk has no mechanical vibration problem. Furthermore, with advance in semiconductor process, the volume of flash memory disk is substantially smaller than a hard disk. Because of extreme portability, flash memory disk has been broadly applied to memory disk, MP3 disk, personal digital assistant (PDA) and mobile phone. In addition, the memory storage capacity of the foregoing devices can be further expanded by adding memory cards formed out of flash memory

A typical flash memory cell includes a control gate, a floating gate, a source and a drain. In general, when electrons are trapped by the oxide-surrounded floating gate in the process of programming the floating gate, then the memory cell is regarded as having a binary bit value ‘0’. When no electrons are trapped inside the floating gate in the process of programming the floating gate, then the memory cell is regarded as having a binary bit value ‘1’.

The capacity of the flash memory disk is obviously related to how many flash memory chips are stacked together and the capacity of single memory chip is obviously related to the processing technique of semiconductors. By moving to more advanced technologies, the semiconductor devices can be scaled down accordingly. For example, if the flash memory device unit's dimension is scaling down by a half, the memory storage capacity can increase four times. The capability of current semiconductor process to fabricate a Giga-byte capacity chip that exceeds earlier 5-inch hard disk is nothing new. However, hard disk memory devices also progress from the 2.5-inch hard disk of a notebook computer to today's micro hard disk (having a diameter of only 1 inch), which is equipped with a storage capacity reaching several tens of Giga-bytes.

To prevent flash memory disk from losing ground in the battle of competition with hard disk storage devices, semiconductor process engineers are working hard to look for innovative scaling down techniques while device design engineers are also searching for better memory device structures. Recently, the so-called SONOS Semiconductor-Oxide-Nitride-Oxide-Semiconductor) structure as an element of flash memory is an example of a successful story for a better memory device structure. FIGS. 1A and 1B show a conventional split-gate flash memory and a stacked flash memory, respectively. The split-gate flash memory and the stacked flash memory have one common characteristic: namely, they both have floating polysilicon gates 10. Regardless of whether the floating polysilicon gate 10 contains doped conductive impurities or not, the electrons injected in a programming operation are evenly distributed inside the floating polysilicon gate 10. Therefore, each flash memory cell can only store a single bit of data.

FIG. 1C shows another conventional stacked flash memory. As shown in FIG. 1C, this newer SONOS (semiconductor/oxide/nitride/oxide/semiconductor) flash memory cell 20 has a different structure. A silicon nitride layer 23 replaces the polysilicon layer. Because oxide layers 22 and 24 are disposed above and below the silicon nitride layer 23, this structure looks like a conventional transistor with an ONO composite layer replacing the O layer. When electrons tunnel through the oxide layer 22 into the silicon nitride layer 23, the electrons lose their mobility almost completely. Instead of distributing evenly within the polysilicon layer, the electrons inside the silicon nitride layer 23 are localized. If the electrons are injected from the source 21, the electrons are stored on side 23a of the nitride layer 23 close to the source 210. On the other hand, if the electrons are injected from the drain 25, the electrons are stored on side 23b of the nitride layer 23 close to the drain 25. In other words, each memory device having the same semiconductor process dimensions can record two bits of data. Therefore, the memory storage capacity is doubled.

One of the advantages of using the SONOS structure is that there are no error bits (tail or fly bits) that are detached from the normal group distribution because the electrical charges are stored inside in the silicon nitride layer 23 and confined by a trap. Therefore, the movement of electrical charges from one trap to another is difficult. Furthermore, if a defect exists somewhere in the oxide layer underneath the silicon nitride layer 23, the probability of electrical charges trapped at a far end moving all the way to the defect is low. Consequently, unlike the floating gate, which is a conductor that allows the electrical charges freedom of movement and increases group leakage and the so-called ‘unreliable error bits’, the SONOS structure has no such problems.

### SUMMARY OF THE INVENTION

Accordingly, the present invention is directed to a NOS non-volatile memory cell having no control gate and capable of storing two bits so as to double the storage capacity of a flash memory chip having identical dimensions and a method of operating the same. The NOS non-volatile memory cell includes an NO storage gate, a first source/drain and a second source/drain. The NO storage gate is disposed on a second conductive type impurity substrate. The NO storage gate includes an oxide layer and a nitride layer disposed in sequence from the second conductive type impurity substrate. The first source/drain and the second source/drain are disposed in the second conductive type impurity substrate on two sides of the NO storage gate, respectively. The locations in the nitride layer close to the first source/drain and the second source/drain are divided into a first bit and a second bit and each location is capable of storing a bit of data. The first source/drain and the second source/drain have the first conductive type impurity dopants.

According to an embodiment of the present invention, the second conductive type impurities are n-type impurities and the first conductive type impurities are p-type impurities.

In an embodiment of the present invention, the NOS non-volatile memory cell is programmed by using band-to-band hot electron injection effect to inject electrons into the nitride layer.

In an embodiment of the present invention, data are read from the NOS non-volatile memory cell through a reverse reading operation. The reverse reading operation includes surrounding the second bit with a depletion region when data is read from the first bit, and furthermore, at least the tapering end of the first channel under the first bit is able to connect with the boundary of the depletion region. The channel under the NO storage gate between the first source/drain and the second source/drain is conductive or not is entirely determined by whether the first channel under the first bit is conductive or not.

In an embodiment of the present invention, data are read from the NOS non-volatile memory cell through a reverse reading operation. The reverse reading operation includes surrounding the first bit with a depletion region when data is read from the second bit, and furthermore, at least the tapering end of the second channel under the second bit is able to connect with the boundary of the depletion region. The channel under the NO storage gate between the second source/drain and the first source/drain is conductive or not is entirely determined by whether the second channel under the second bit is conductive or not.

In an embodiment of the present invention, data are erased from the NOS non-volatile memory cell by using band-to-band hot hole injection effect to neutralize the electrons in the nitride layer.

In an embodiment of the present invention, the second conductive type impurity substrate is an n-well or an n-type substrate.

In an embodiment of the present invention, the first conductive type impurities are n-type impurities and the second conductive type impurities are p-type impurities.

In an embodiment of the present invention, the NOS non-volatile memory cell is programmed by using band-to-band hot hole injection effect to inject holes into the nitride layer.

In an embodiment of the present invention, data are read from the NOS non-volatile memory cell through a reverse reading operation. The reverse reading operation includes surrounding the second bit with a depletion region when data is read from the first bit, and furthermore, at least the tapering end of the first channel under the first bit is able to connect with the boundary of the depletion region. The channel under the NO storage gate between the first source/drain and the second source/drain is conductive or not is entirely determined by whether the first channel under the first bit is conductive or not.

In an embodiment of the present invention, data are read from the NOS non-volatile memory cell through a reverse reading operation. The reverse reading operation includes surrounding the first bit with a depletion region when data is read from the second bit, and furthermore, at least the tapering end of the second channel under the second bit is able to connect with the boundary of the depletion region. The channel under the NO storage gate between the second source/drain and the first source/drain is conductive or not is entirely determined by whether the second channel under the second bit is conductive or not.

In an embodiment of the present invention, data are erased from the NOS non-volatile memory cell by using band-to-band hot electron injection effect to neutralize the holes in the nitride layer.

In an embodiment of the present invention, the second conductive type impurity substrate is a p-well or a p-type substrate.

The present invention also provides a method of operating the foregoing NOS non-volatile memory cell. The method includes injecting carriers into the nitride layer using band-to-band hot carrier injection effect so as to program the NOS non-volatile memory cell. When the second conductive type impurities are n-type impurities, the second source/drain is floating, a first voltage, which is negative with respect to the substrate, is applied to the first source/drain, and a second voltage is applied to the substrate so as to program the first bit.

The present invention also provides a method of operating the foregoing NOS non-volatile memory cell. The method includes injecting carriers into the nitride layer using band-to-band hot carrier injection effect so as to program the NOS non-volatile memory cell. When the second conductive type impurities are n-type impurities, the first source/drain is floating, a third voltage, which is negative with respect to the substrate, is applied to the second source/drain, and a fourth voltage is applied to the substrate so as to program the second bit.

The present invention also provides a method of operating the foregoing NOS non-volatile memory cell. The method includes applying a fifth voltage, which is negative with respect to the substrate and the first source/drain, to the second source/drain, applying a sixth voltage to the first source/drain and applying a seventh voltage to the substrate so as to read data from the first bit of the NOS non-volatile memory cell when the second conductive type impurities are n-type impurities. The fifth voltage must be sufficiently large to ensure the tapering end of the first channel under the first bit can connect with the boundary of the depletion region enabled by the fifth voltage. Consequently, the channel under the NO storage gate between the first source/drain and the second source/drain is conductive or not is entirely determined by whether the first channel under the first bit is conductive or not.

The present invention also provides a method of operating the foregoing NOS non-volatile memory cell. The method includes applying an eighth voltage, which is negative with respect to the substrate and the second source/drain, to the first source/drain, applying a ninth voltage to the second source/drain and applying a tenth voltage to the substrate so as to read data from the second bit of the NOS non-volatile memory cell when the second conductive type impurities are n-type impurities. The eighth voltage must be sufficiently large to ensure the tapering end of the second channel under the second bit can connect with the boundary of the depletion region enabled by the eighth voltage. Consequently, the channel under the NO storage gate between the second source/drain and the first source/drain is conductive or not is entirely determined by whether the second channel under the second bit is conductive or not.

The present invention also provides a method of operating the foregoing NOS non-volatile memory cell. The method includes injecting first type carriers so as to remove second type carriers having an opposite polarity to the first type carriers inside the nitride layer originally. This is achieved by using band-to-band hot carrier injection effect to erase data from the NOS non-volatile memory cell. When the second conductive type impurities are n-type impurities, the second source/drain is floating, an eleventh voltage, which is negative with respect to the substrate, is applied to the first source/drain, and a twelfth voltage is applied to the substrate so as to erase the first bit.

The present invention also provides a method of operating the foregoing NOS non-volatile memory cell. The method includes injecting first type carriers so as to remove second type carriers having an opposite polarity to the first type carriers inside the nitride layer originally. This is achieved by using band-to-band hot carrier injection effect to erase data from the NOS non-volatile memory cell. When the second conductive type impurities are n-type impurities, the first source/drain is floating, a thirteenth voltage, which is negative with respect to the substrate, is applied to the second source/drain, and a fourteenth voltage is applied to the substrate so as to erase the second bit.

The present invention also provides a method of operating the foregoing NOS non-volatile memory cell. The method includes injecting carriers into the nitride layer using band-to-band hot carrier injection effect so as to program the NOS non-volatile memory cell. When the second conductive type impurities are p-type impurities, the second source/drain is floating, a fifteenth voltage, which is positive with respect to the substrate, is applied to the first source/drain, and a sixteenth voltage is applied to the substrate so as to program the first bit.

The present invention also provides a method of operating the foregoing NOS non-volatile memory cell. The method includes injecting carriers into the nitride layer using band-to-band hot carrier injection effect so as to program the NOS non-volatile memory cell. When the second conductive type impurities are p-type impurities, the first source/drain is floating, a seventeenth voltage, which is positive with respect to the substrate, is applied to the second source/drain, and an eighteenth voltage is applied to the substrate so as to program the second bit.

The present invention also provides a method of operating the foregoing NOS non-volatile memory cell. The method includes applying a nineteenth voltage, which is positive with respect to the substrate and the first source/drain, to the second source/drain, applying a twentieth voltage to the first source/drain and applying a twenty-first voltage to the substrate so as to read data from the first bit of the NOS non-volatile memory cell when the second conductive type impurities are p-type impurities. The nineteenth voltage must be sufficiently large to ensure the tapering end of the first channel under the first bit can connect with the boundary of the depletion region enabled by the nineteenth voltage. Consequently, the channel under the NO storage gate between the first source/drain and the second source/drain is conductive or not is entirely determined by whether the first channel under the first bit is conductive or not.

The present invention also provides a method of operating the foregoing NOS non-volatile memory cell. The method includes applying an twenty-second voltage, which is positive with respect to the substrate and the second source/drain, to the first source/drain, applying a twenty-third voltage to the second source/drain and applying a twenty-fourth voltage to the substrate so as to read data from the second bit of the NOS non-volatile memory cell when the second conductive type impurities are p-type impurities. The twenty-second voltage must be sufficiently large to ensure the tapering end of the second channel under the second bit can connect with the boundary of the depletion region enabled by the twenty-second voltage. Consequently, the channel under the NO storage gate between the second source/drain and the first source/drain is conductive or not is entirely determined by whether the second channel under the second bit is conductive or not.

The present invention also provides a method of operating the foregoing NOS non-volatile memory cell. The method includes injecting first type carriers so as to remove second type carriers having an opposite polarity to the first type carriers inside the nitride layer originally. This is achieved by using band-to-band hot carrier injection effect to erase data from the NOS non-volatile memory cell. When the second conductive type impurities are p-type impurities, the second source/drain is floating, and a twenty-fifth voltage, which is positive with respect to the substrate, is applied to the first source/drain, and a twenty-sixth voltage is applied to the substrate so as to erase the first bit.

The present invention also provides a method of operating the foregoing NOS non-volatile memory cell. The method includes injecting first type carriers so as to remove second type carriers having an opposite polarity to the first type carriers inside the nitride layer using band-to-band hot carrier injection effect to erase data from the NOS non-volatile memory cell. When the second conductive type impurities are p-type impurities, the first source/drain is floating, and a twenty-seventh voltage, which is positive with respect to the substrate, is applied to the second source/drain, and a twenty-eighth voltage is applied to the substrate so as to erase the second bit.

To program the NOS non-volatile memory cell of the present invention, the carriers is injected into the nitride layer of the selected bit using band-to-band hot carrier injection effect. For a p-type (n-type) NOS non-volatile memory cell, the band-to-band hot carrier injection effect is produced when a voltage, which is negative (or positive) with respect to the substrate, is applied to the source/drain adjacent to the selected bit, the source/drain adjacent to the unselected bit is floating, and the substrate (n-well or p-well) is connected to a substrate voltage.

The reverse reading operation is used to read data from the NOS non-volatile memory cell to shield the unselected bit against interference. For a p-type (n-type) NOS non-volatile memory cell, a voltage, which is negative (or positive) with respect to the substrate and the source/drain adjacent to the selected bit, is applied to the source/drain adjacent to the unselected bit, and a constant voltage is applied to the source/drain adjacent to the selected bit while a substrate voltage is applied to the substrate (n-well or p-well). The negative (or positive) voltage applied to the source/drain adjacent to the unselected bit must be sufficiently large to ensure the tapering end of the channel under the selected bit can connect with the boundary of the depletion region enabled by the negative (or positive) voltage. Thus, the channel under the NO storage gate between the source/drain adjacent to the unselected bit and the source/drain adjacent to the selected bit is conductive or not is entirely determined by whether the channel under the selected bit is conductive or not.

To erase the NOS non-volatile memory cell of the present invention, the electrons are neutralized in the nitride layer at the same side of the selected bit using band-to-band hot hole injection effect. The erasing method utilizes band-to-band hot hole injection to remove the electrons in the nitride layer at the same side of the selected bit. For a p-type (n-type) NOS non-volatile memory cell, the method is floating the source/drain adjacent to the unselected bit and applying a voltage, which is negative (positive) with respect to the substrate, to the source/drain adjacent to the selected bit, and applying a substrate voltage to the substrate.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic cross-sectional view of a conventional split-gate flash memory.

FIG. 1B is a schematic cross-sectional view of a conventional stacked flash memory.

FIG. 1C is a schematic cross-sectional view of a conventional SONOS flash memory having two bit per cell storage capacity.

FIG. 2A is a schematic cross-sectional view of a p-type NOS non-volatile memory cell having no control gate formed according to a method of the present invention.

FIG. 2B is a schematic cross-sectional view of a p-type NOS non-volatile memory cell having no control gate according to a first preferred embodiment of the present invention using band-to-band hot electron injection to inject electrons into the right side of the memory cell in a programming operation.

FIG. 2C is a schematic cross-sectional view of a p-type NOS non-volatile memory cell having no control gate according to the first preferred embodiment of the present invention using a reverse reading operation to read out the data on the right side of the memory cell.

FIG. 2D is a schematic cross-sectional view of a p-type NOS non-volatile memory cell having no control gate according to the first preferred embodiment of the present invention using band-to-band hot hole injection to inject holes into the nitride layer so as to generate electron-hole recombination and perform an erasing operation.

FIG. 3 is a schematic cross-sectional view of a NOS non-volatile memory cell having no control gate according to a second preferred embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

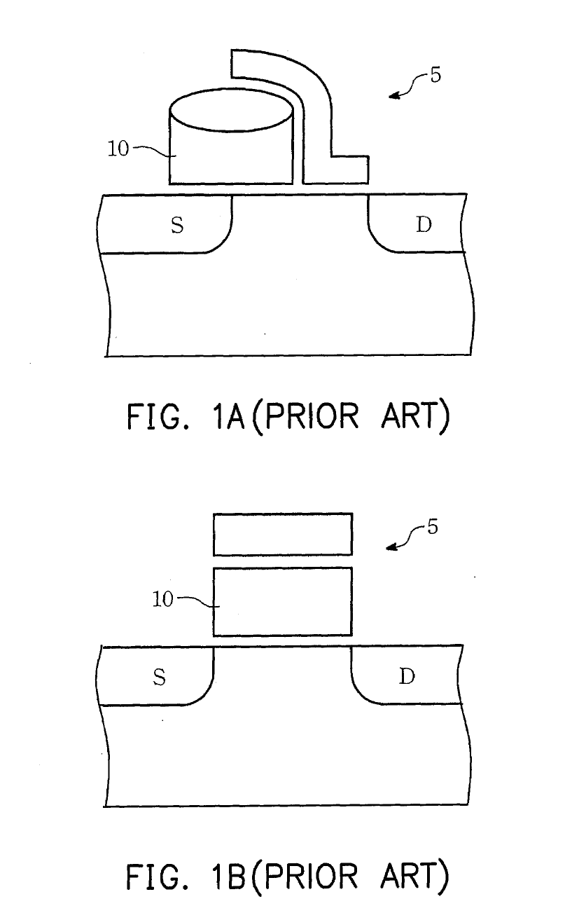

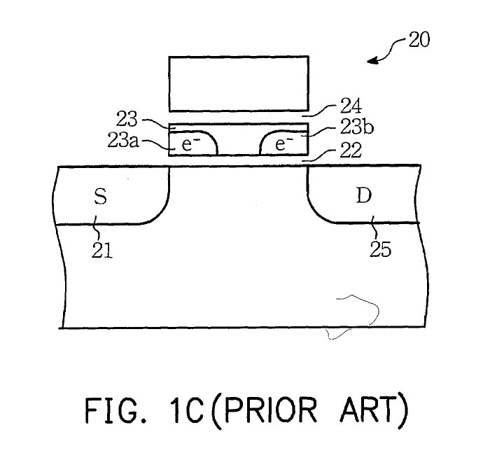

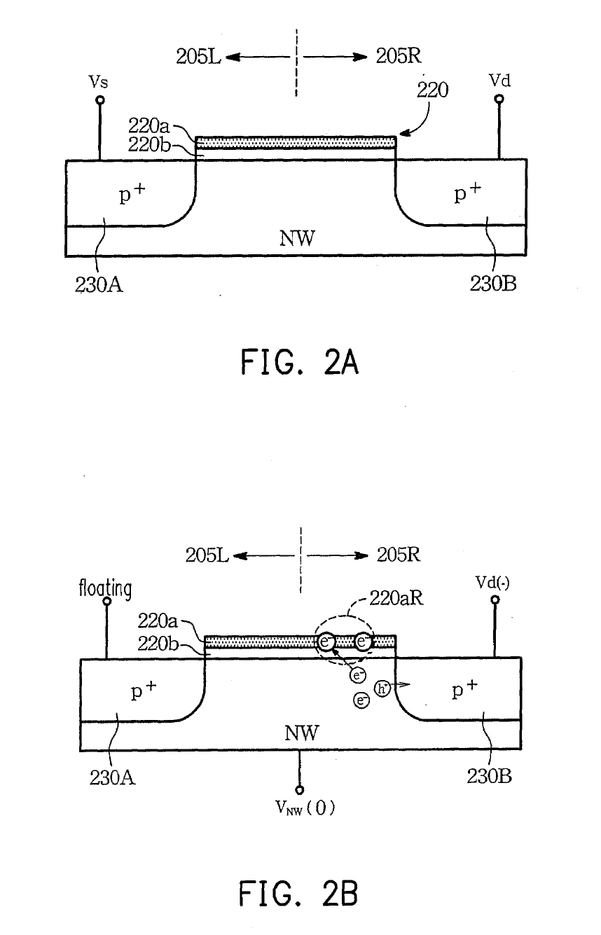

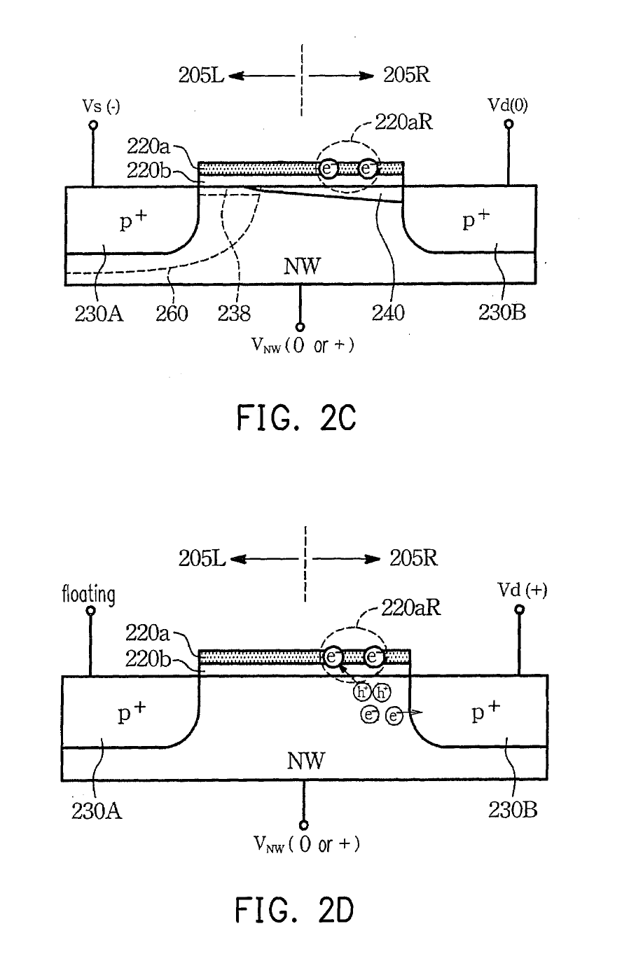

The present invention discloses a new type of NOS (from top to bottom, a nitride layer N, an oxide layer 0 and a semiconductor layer S) non-volatile memory. As show in FIG. 2A, the NOS memory cell has a simpler structure compared to the SONOS memory cell (FIG. 1C) in the prior technique. The NOS memory cell of the present invention has an identical structure to the conventional technique besides having no polysilicon control gate. Furthermore, the memory can be programmed, read and erased by using the operating methods of the present invention. In particular, two bits of data can be stored in each memory cell and any one of the bits can be independently operated on without interference from the other bit. Therefore, the NOS memory cell of the present invention is able to achieve a doubling the memory storage capacity at the same dimension. Moreover, the process is simpler and thickness of the device is reduced.

According to a preferred embodiment of the present invention, the present invention is a p-type NOS non-volatile memory cell formed in an n-well (NW) of a CMOS process. As shown in the schematic cross-section in FIG. 2A, the NOS non-volatile memory cell includes an NO storage gate 220, a source/drain 230A and a source/drain 230B.

The NO storage gate 220 is disposed on the n-well (or an n-type substrate base). The NO storage gate 220 includes an oxide layer 220b and a nitride layer 220a disposed in sequence from the n-well (or n-type substrate).

The source/drain 230A and the source/drain 230B are disposed in the n-well (or n-type substrate) at two sides of the NO storage gate 220. The source/drain 230A and the source/drain 230B are p+ regions produced by a heavy doping of p-type impurities.

Using the middle line of the NOS storage gate 220 (including the nitride layer 220a and the oxide layer 220b) as a reference, the NOS non-volatile memory cell can be divided into a left bit 205L and a right bit 205R. In other words, the nitride layer 220 close to the source/drain 230A and close to the source/drain 230B can be regarded as the locations of the left bit 205L and the right bit 205R, respectively, and each of these locations can store one bit of data.

Because of the NOS memory cell differs from the conventional SONOS structure in having no control gate, the NO storage gate 220 (including the nitride layer 220a and the oxide layer 220b) and the source/drain 230A and the source/drain 230B are names to facilitate description. In addition, the labels 205L and 205R for naming the left bit and the right bit are also used to facilitate description because correct programming, reading or erasing operation of any bit requires the cooperation of both the source/drain 230A and the source/drain 230B.

Next, programming, reading and erasing operations of bit 205R are illustrated with reference to FIGS. 2B˜2D. Furthermore, the operations of bit 205L are similar to the operations of bit 205R. The only difference is that the voltages applied to the source/drain 230A and the source/drain 230B are switched. Therefore, by illustrating the operations of one of the bits, for example, bit 205R, and the operations of the other bit 205L can be deduced. Here, only the programming, reading and erasing operations of bit 205R are described in detail while the same operations of bit 205L is omitted.

To program bit 205R of the NOS memory cell, the present invention utilizes band-to-band hot electron injection effect.

First, to program a data ‘1’ into bit 205R of the NOS memory cell, the source/drain 230A is floating, a 0V is applied to the NW body, labeled V_{NW} (0V), and a negative voltage Vd (−) is applied to the source/drain 230B. As a result, a reverse bias effect is produced between the source/drain 230B and the body (the NW body) of the transistor, and the positive and negative space charges generate an electric field between the source/drain 230B and the NW body. When the electric field produced by the reverse bias voltage is sufficiently large, more electron-hole pairs are generated because the Fermi energy levels of the filled energy levels of the valence band in the source/drain 230B are higher than the empty energy levels of the conduction band in the n-well NW so that the filled energy levels of the valence band of the source/drain 230B have a high probability of jumping across the depletion region into the empty energy levels of the conduction band in the n-well NW and creating electrons and holes in pairs in the source/drain 230B and the n-well NW, respectively. The energy-carrying electrons are accelerated by the electric field. Therefore, as long as the bottom oxide layer 220B of the NO storage gate 220 is sufficiently thin, for example, 10 nm or smaller, the electrons have a high probability of tunneling through the oxide layer 220b into the nitride layer 220a. Similar to the prior technique, the electrons injected into the nitride layer 220a are confined to the location 220aR in the nitride layer 220a close to the source/drain 230B.

Conversely, to program a data ‘1’ into bit 205L of the NOS memory cell, the source/drain 230B is floating, a 0V is applied to the NW body, labeled V_{NW} (0V), and a negative voltage Vd (−) is applied to the source/drain 230A.

The method of reading data from bit 205R of the NOS non-volatile memory cell is described with reference to bias voltages applied to various electrodes as shown in FIG. 2C. Because bit 205R and bit 205L are both stored in the same nitride layer 220a of the storage gate 220, the reading of data from the NOS bit 205R must avoid being interfered or affected by bit 205L. In the present invention, a reverse reading operation is used. To read data from bit 205R of the NOS memory cell, a negative voltage Vs (−) is applied to the source/drain 230A, 0V is applied to the source/drain 230B, that is, Vd (0V), 0V or a positive voltage V_{NW} (0V or +V) is applied to the NW body. The electric field produced under these bias voltages generates a depletion region 260 that can be used to enclose or shield bit 205L of the NOS memory cell. Conversely, to read data from bit 205L of the NOS memory cell, a negative voltage (−) is applied to the source/drain 230B, that is, Vd (−V), 0V is applied to the source/drain 230A, that is, Vs (0V), and 0V or a positive voltage is applied to the NW body, that is, V_{NW} (0V or +V) so as to shield against bit 205R of the NOS memory cell.

As shown in FIG. 2C, the reading of data from bit 205R of the NOS memory cell is used as an example. When electrons are not stored in bit 205R of the NOS memory cell, the nitride layer 220aR has no electrons and no inversion layer is formed between the right side of the NO storage gate 220 (including the nitride layer 220a and the oxide layer 220b) and the source/drain 230B. As a result, no hole current flows from the source/drain 230B to the source/drain 230A. Conversely, when electrons are stored in bit 205R of the NOS memory cell, the nitride layer 220aR has enough electrons to produce a channel 240 built out of an inversion layer that forms between the right side of the NO storage gate 220 (including the nitride layer 220a and the oxide layer 220b) and the source/drain 230B. As shown in FIG. 2C, the channel 240 is tapering toward the left. To ensure any hole current that flows from the source/drain 230B to the source/drain 230A can be read, the tapering end of the channel 240 must at least connect with the depletion region 260 formed by the reverse bias voltage between the source/drain 230A and the NW body. In other words, the voltage Vs (−) must be sufficiently negative. When the tapering end of the channel 240 is connected with the depletion region 260, the holes arriving at the depletion region 260 from the source/drain 230B will be accelerated by the electric field generated by the space charges, thereby forming a channel 238 that connects with the channel 240.

As shown in FIG. 2D, data is erased from the NOS non-volatile memory cell by band-to-band hot hole injection effect. To erase data stored in bit 205R, the voltage applied to each electrode is as shown in FIG. 2D, namely, the source/drain 230A is floating, 0V or a positive voltage is applied to the NW body, that is, V_{NW} (0V or +V), and a negative voltage (−), that is, Vd (−) is applied to the source/drain 230B. As a result, a reverse bias voltage is generated between the source/drain 230B and the NW body. In a way, this is similar to the band-to-band hot electron injection effect in the programming operation shown in FIG. 2B. However, this time the holes thus generated are attracted by the electrons concentrated around the location 220aR of the NO storage gate 220 and initiate electron-hole recombination so as to erase the data in bit 205R. Conversely, to erase the data in bit 205L of the NOS memory cell, the source/drain 230B is floating, 0V or a positive voltage is applied to the NW body, that is, V_{NW} (0V or +V), and a negative voltage (−), that is, Vd (−) is applied to the source/drain 230A.

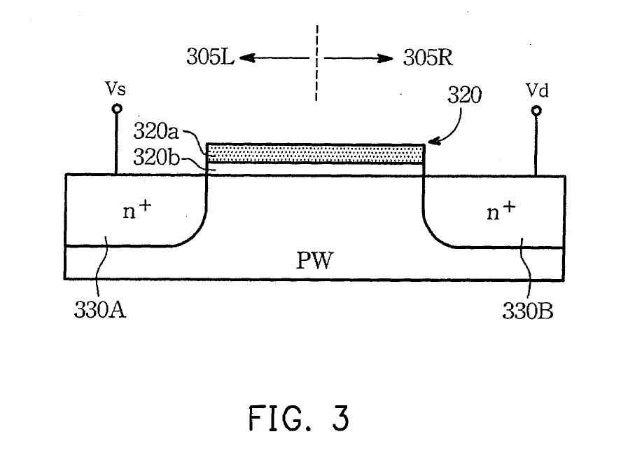

In the foregoing preferred embodiments, p-type NOS non-volatile memory cell is used as an example in the description. However, this is not intended to limit the claims of the present invention. For example, the present invention can also be adopted in an n-type NOS non-volatile memory cell as shown in FIG. 3.

The n-type NOS non-volatile memory cell as shown in FIG. 3 is formed in a p-well (PW) and includes a source/drain 330A, a source/drain 330B and an NO storage gate 320 (including a nitride layer 320a and an oxide layer 320b). The source/drain 330A and the source/drain 330B are heavily doped using n-type conductive impurities. In addition, the operating voltages of the n-type NOS non-volatile memory cell are opposite to that of the p-type NOS non-volatile memory cell.

Table 1 is a table showing the states of the applied bias voltages when performing a programming operation, a reading operation or an erasing operation of bit 205R or 305R for p-type and n-type NOS non-volatile memory cells.

TABLE 1

| | Bias voltage of each electrode | p-type NOS | n-type NOS |
|---|---|---|---|
| Programming | Source/drain(230A, 330A)Vs | Floating | Floating |
| | Source/drain(230B, 330B) Vd | Negative Voltage | Positive Voltage |
| | Substrate or well NW (PW)V_{NW} | 0 V | 0 V |
| | (V_{PW}) | | |
| Reading | Source/drain (230A, 330A)Vs | Negative Voltage | Positive Voltage |
| | Source/drain (230B, 330B) Vd | 0 V | 0 V |
| | Substrate or well NW (PW)V_{NW} | 0 V | 0 V |
| | (V_{PW}) | | |
| Erasing | Source/drain (230A, 330A)Vs | Floating | Floating |
| | Source/drain (230B, 330B) Vd | Negative Voltage | Positive Voltage |
| | Substrate or well NW (PW)V_{NW} | 0 V or Positive | 0 V or Negative |
| | (V_{PW}) | voltage | voltage |

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A nitride/oxide/semiconductor (NOS) non-volatile memory cell, disposed on a second conductive type impurity substrate, comprising:
a nitride/oxide (NO) storage gate, disposed on the second conductive type impurity substrate, and comprising, in sequence from the second conductive type impurity substrate, an oxide layer and a nitride layer; and
a first source/drain and a second source/drain, disposed in the second conductive type impurity substrate at two sides of the NO storage gate, wherein locations in the nitride layer close to the first source/drain and close to the second source/drain are a first bit and a second bit, respectively, each of which is capable of storing one bit of data, and the first source/drain and the second source/drain have a first conductive type impurity dopants.

2. The NOS non-volatile memory cell according to claim 1, wherein the second conductive type impurities are n-type impurities and the first conductive type impurities are p-type impurities.

3. The NOS non-volatile memory cell according to claim 2, wherein electrons are injected into the nitride layer by band-to-band hot electron injection effect in a programming operation of the NOS non-volatile memory cell.

4. The NOS non-volatile memory cell according to claim 2, wherein a reverse reading operation is used to read data from the NOS non-volatile memory cell, the reverse reading operation comprises surrounding the second bit with a depletion region such that at least one tapering end of a first channel under the first bit connects with a boundary of the depletion region when data is read from the first bit, and as a result, the channel under the NO storage gate between the first source/drain and the second source/drain is conductive or not is completely determined by whether the first channel under the first bit is conductive or not.

5. The NOS non-volatile memory cell according to claim 2, wherein a reverse reading operation is used to read data from the NOS non-volatile memory cell, the reverse reading operation comprises surrounding the first bit with a depletion region such that at least one tapering end of a second channel under the second bit connects with a boundary of the depletion region when data is read from the second bit, and as a result, the channel under the NO storage gate between the second source/drain and the first source/drain is conductive or not is completely determined by whether the second channel under the second bit is conductive or not.

6. The NOS non-volatile memory cell according to claim 2, wherein band-to-band hot hole injection effect is used for neutralizing the electrons in the nitride layer in an erasing operation of the NOS non-volatile memory cell.

7. The NOS non-volatile memory cell according to claim 2, wherein the second conductive type impurity substrate is an n-well or an n-type substrate.

8. The NOS non-volatile memory cell according to claim 1, wherein the first conductive type impurities are n-type impurities and the second conductive type impurities are p-type impurities.

9. The NOS non-volatile memory cell according to claim 8, wherein holes are injected into the nitride layer by band-to-band hot hole injection effect in a programming operation of the NOS non-volatile memory cell.

10. The NOS non-volatile memory cell according to claim 8, wherein a reverse reading operation is used to read data from the NOS non-volatile memory cell, the reverse reading operation comprises surrounding the second bit with a depletion region such that at least one tapering end of a first channel under the first bit connects with a boundary of the depletion region when data is read from the first bit, and as a result, the channel under the NO storage gate between the first source/drain and the second source/drain is conductive or not is completely determined by whether the first channel under the first bit is conductive or not.

11. The NOS non-volatile memory cell according to claim 8, wherein a reverse reading operation is used to read data from the NOS non-volatile memory cell, the reverse reading operation comprises surrounding the first bit with a depletion region such that at least one tapering end of a second channel under the second bit connects with a boundary of the depletion region when data is read from the second bit, and as a result, the channel under the NO storage gate between the second source/drain and the first source/drain is conductive or not is completely determined by whether the second channel under the second bit is conductive or not.

12. The NOS non-volatile memory cell according to claim 8, wherein holes in the nitride layer are neutralized by band-to-band hot electron injection effect in an erasing operation of the NOS non-volatile memory cell.

13. The NOS non-volatile memory cell according to claim 8, wherein the second conductive type impurity substrate is a p-well or a p-type substrate.

14. A method of operating the NOS non-volatile memory cell according to claim 1, comprising: when the second conductive type impurities are n-type impurities, floating the second source/drain; applying a first voltage, which is negative with respect to the substrate, to the first source/drain; and applying a second voltage to the substrate to program the first bit using band-to-band hot carrier injection effect to inject carriers into the nitride layer in a programming operation of the NOS non-volatile memory cell.

15. A method of operating the NOS non-volatile memory cell according to claim 1, comprising: when the second conductive type impurities are n-type impurities, floating the first source/drain; applying a third voltage, which is negative with respect to the substrate, to the second source/drain; and applying a fourth voltage to the substrate to program the second bit using band-to-band hot carrier injection effect to inject carriers into the nitride layer in a programming operation of the NOS non-volatile memory cell.

16. A method of operating the NOS non-volatile memory cell according to claim 1, comprising: when data are read from the first bit of the NOS non-volatile memory cell and the second conductive type impurities are n-type impurities, applying a fifth voltage, which is negative with respect to the substrate and the first source/drain, to the second source/drain; applying a sixth voltage to the first source/drain; and applying a seventh voltage to the substrate, wherein the fifth voltage is sufficiently large to ensure the tapering end of the first channel under the first bit connects with the boundary of the depletion region enabled by the fifth voltage, and as a result, the channel under the NO storage gate between the first source/drain and the second source/drain is conductive or not is completely determined by whether the first channel under the first bit is conductive or not.

17. A method of operating the NOS non-volatile memory cell according to claim 1, comprising: when data are read from the second bit of the NOS non-volatile memory cell and the second conductive type impurities are n-type impurities, applying an eighth voltage, which is negative with respect to the substrate and the second source/drain, to the first source/drain; applying a ninth voltage to the second source/drain; and applying a tenth voltage to the substrate, wherein the eighth voltage is sufficiently large to ensure the tapering end of the second channel under the second bit connects with the boundary of the depletion region enabled by the eighth voltage, and as a result, the channel under the NO storage gate between the second source/drain and the first source/drain is conductive or not is completely determined by whether the second channel under the second bit is conductive or not.

18. A method of operating the NOS non-volatile memory cell according to claim 1, comprising: when the second conductive type impurities are n-type impurities, floating the second source/drain; applying an eleventh voltage, which is negative with respect to the substrate, to the first source/drain; and applying a twelfth voltage to the substrate to erase the first bit using band-to-band hot carrier injection effect in an erasing operation of the NOS non-volatile memory cell, wherein first type carriers are injected into the nitride layer so as to remove second type carriers stored in the nitride layer.

19. A method of operating the NOS non-volatile memory cell according to claim 1, comprising: when the second conductive type impurities are n-type impurities, floating the first source/drain; applying an thirteenth voltage, which is negative with respect to the substrate, to the second source/drain; and applying a fourteenth voltage to the substrate to erase the second bit using band-to-band hot carrier injection effect in an erasing operation of the NOS non-volatile memory cell, wherein first type carriers are injected into the nitride layer so as to remove second type carriers stored in the nitride layer.

20. A method of operating the NOS non-volatile memory cell according to claim 1, comprising: when the second conductive type impurities are p-type impurities, floating the second source/drain floating; applying a fifteenth voltage, which is positive with respect to the substrate, to the first source/drain; and applying a sixteenth voltage to the substrate to program the first bit using band-to-band hot carrier injection effect to inject carriers into the nitride layer in a programming operation of the NOS non-volatile memory cell.

21. A method of operating the NOS non-volatile memory cell according to claim 1, comprising: when the second conductive type impurities are p-type impurities, floating the first source/drain; applying a seventeenth voltage, which is positive with respect to the substrate, to the second source/drain; and applying an eighteenth voltage to the substrate to program the second bit using band-to-band hot carrier injection effect to inject carriers into the nitride layer in a programming operation of the NOS non-volatile memory cell.

22. A method of operating the NOS non-volatile memory cell according to claim 1, comprising: when data are read from the first bit of the NOS non-volatile memory cell and the second conductive type impurities are p-type impurities, applying a nineteenth voltage, which is positive with respect to the substrate, to the second source/drain; applying a twentieth voltage to the first source/drain; and applying a twenty-first voltage to the substrate, wherein the nineteenth voltage is sufficiently large to ensure the tapering end of the first channel under the first bit connects with the boundary of the depletion region enabled by the nineteenth voltage, and as a result, the channel under the NO storage gate between the first source/drain and the second source/drain is conductive or not is completely determined by whether the first channel under the first bit is conductive or not.

23. A method of operating the NOS non-volatile memory cell according to claim 1, comprising: when data are read from the second bit of the NOS non-volatile memory cell and the second conductive type impurities are p-type impurities, applying a twenty-second voltage, which is positive with respect to the substrate, to the first source/drain; applying a twenty-third voltage to the second source/drain; and applying a twenty-fourth voltage to the substrate, wherein the twenty-second voltage is sufficiently large to ensure the tapering end of the second channel under the second bit connects with the boundary of the depletion region enabled by the twenty-second voltage, and as a result, the channel under the NO storage gate between the second source/drain and the first source/drain is conductive or not is completely determined by whether the second channel under the second bit is conductive or not.

24. A method of operating the NOS non-volatile memory cell according to claim 1, comprising: when the second conductive type impurities are p-type impurities, floating the second source/drain; applying a twenty-fifth voltage, which is positive with respect to the substrate, to the first source/drain; and applying a twenty-sixth voltage to the substrate so as to erase the first bit using band-to-band hot carrier injection effect in an erasing operation of the NOS non-volatile memory cell, wherein first type carriers are injected into the nitride layer so as to remove second type carriers stored in the nitride layer.

25. A method of operating the NOS non-volatile memory cell according to claim 1, comprising: when the second conductive type impurities are p-type impurities, floating the first source/drain; applying a twenty-seventh voltage, which is positive with respect to the substrate, to the second source/drain; and applying a twenty-eighth voltage to the substrate so as to erase the second bit using band-to-band hot carrier injection effect in an erasing operation of the NOS non-volatile memory cell, wherein first type carriers are injected into the nitride layer so as to remove second type carriers stored in the nitride layer.
